(19) United States
(12) Patent Application Publication
(10) Pub. No.: US 2007/0169808 A1
(43) Pub. Date: Jul. 26, 2007

(54) Solar cell

(76) Inventors: Nazir Pyarali Kherani, Toronto (CA); Bhanu Gangadhar Rayaprol, Etobicoke (CA); Davit Yeghikyan, Toronto (CA); Stefan Zukotynski, Richmond Hill (CA)

Correspondence Address: Ralph A. Dowell of DOWELL & DOWELL P.C., 2111 Eisenhower Ave, Suite 406, Alexandria, VA, 22314, US

(21) Appl. No.: 11/339,851

(22) Filed: Jan. 26, 2006

(51) Int. Cl. H01L 31/00

(52) U.S. Cl. 136/258

(57) ABSTRACT

The present invention provides a thin film amorphous silicon-crystalline silicon back heterojunction and back surface field device configuration for a heterojunction solar cell. The configuration is attained by the formation of heterojunctions on the back surface of crystalline silicon at low temperatures. Low temperature fabrication allows for the application of low resolution lithography and/or shadow masking processes to produce the structures. The heterojunctions and interface passivation can be formed through a variety of material compositions and deposition processes, including appropriate surface restructing techniques. The configuration achieves separation of optimization requirements for light absorption and carrier generation at the front surface on which the light is incident, and in the bulk, and charge carrier collection at the back of the device. The shadowing losses are eliminated by positioning the electrical contacts at the back thereby removing them from the path of the incident light. Back contacts need optimization only for maximum charge carrier collection without bothering about shading losses. A range of elements/alloys may be used to effect band-bending. All of the above features result in a very high efficiency solar cell. The open circuit voltage of the back heterojunction device is higher than that of an all-crystalline device. The solar cell configurations are equally amenable to crystalline silicon wafer absorber as well as thin silicon layers formed by using a variety of fabrication processes. The configurations can be used for radiovoltaic and electron-voltaic energy conversion devices.

### FIELD OF THE INVENTION

The present invention relates to thin film back-heterojunction, amorphous-crystalline silicon photovoltaic devices produced at low-temperatures.

### BACKGROUND OF THE INVENTION

Most of the present day silicon photovoltaic devices are configured so that a p-n junction is formed in silicon by diffusion of dopants at elevated temperatures and the application of electrodes on the light facing side and back-side. Back contacts on silicon photovoltaic devices are formed, using high temperature processing, to substantially overcome the shading losses on the light facing side. Amorphous-crystalline silicon heterojunction photovoltaic devices are formed by the deposition of amorphous silicon layers on crystalline silicon, thereby substantially providing for low temperature processing. In this case, the electrodes are applied on the light facing front side as well as back-side of the device.

JP 18413358 to Hamakawa et al., and U.S. Pat. No. 4,496,788 disclose amorphous (microcrystalline)/crystalline semiconductor heterojunction solar cells. JP application S62-128572 to Nitta Kyocera disclose amorphous (or mc)-Si/a-Si (I)/crystalline Si heterojunction solar cells. JP 2740284 to Iwamoto et al. and U.S. Pat. No. 5,066,340 disclose amorphous Si/(mc)-Si (I)/crystalline Si heterojunction solar cells. JP 2132527 to Noguchi et al. and U.S. Pat. No. 5,213,628 disclose amorphous (P or N)/amorphous (I)/crystalline (N or P) heterojunction solar cells.

U.S. Pat. No. 4,487,989 discloses a contact for a solar cell. U.S. Pat. No. 5,641,362 discloses a structure and fabrication process for an aluminum alloy junction. U.S. Pat. No. 4,927,770 is directed to a method of fabricating back surface point contact for solar cells.

There are several drawbacks to the prior art silicon photovoltaic devices, namely the front surface of the device that includes electrodes which block and absorb light, preventing it from reaching the underlying active silicon layer and thereby reducing the photogeneration of electron-hole pairs in the active silicon layer of the device. The presence of the electrical contacts on the front surface makes it problematic for applying an optimal antireflection layer on the front surface, since with the electrical contacts on the front surface they need to be both optically transmissive and electrically conductive. Further, since the contacts are in the path of the incident light, the electrical contacts and buses on the front surface cannot be significantly increased in size in order to further reduce the series resistance.

Prior art silicon photovoltaic devices that include contacts at the back, namely back contact photovoltaic devices, also exhibit several shortcomings. These devices are fabricated using high temperature processes such as thermal diffusion of dopants and growth of passivation and antireflection coatings. With the trend favouring the use of thin silicon wafers, these high temperature processes would lead to thermal damage. Also, use of high temperature processing increases the cost of processing and thus the cost of the device. In addition, these back contact photovoltaic devices invariably require high resolution photolithography and associated semiconductor processing.

Prior art silicon photovoltaic devices that use low temperature processing, namely amorphous-crystalline silicon heterojunction photovoltaic devices, also exhibit several shortcomings. The front surface of these devices includes electrodes which block and absorb light, reducing the light reaching the underlying active silicon layer and thereby reducing the photogeneration of carriers in the device. The presence of the electrical contacts on the front surface makes it problematic for applying an optimal antireflection layer on the front surface, since with the electrical contacts on the front surface they need to be both optically transmissive and electrically conductive. Further, since the contacts are in the path of the incident light, the electrical contacts and buses on the front surface cannot be significantly increased in size in order to further reduce the series resistance.

Therefore it would be very advantageous to fabricate a low temperature, thin film back-heterojunction, amorphous-crystalline silicon photovoltaic device in which the electrical contacts are delegated to the back surface. This eliminates shading losses, as well as permitting the application of an optimal antireflection layer on the front surface. Due to low temperature processing, this is amenable to the use of thinner wafers. Also, the device is amenable to the use of low resolution photolithography and simple shadow-masking methods. This novel device opens the way to future device developments in addition to addressing the above described shortcomings of the prior art.

### SUMMARY OF THE INVENTION

The present invention describes a novel heterojunction solar cell having thin film amorphous silicon—crystalline silicon back heterojunction and back surface field device configuration prepared at low temperatures. In contrast to present day back junction devices, the back heterojunction device is fabricated by employing low cost processes. These include deposition of thin film layers at low temperature and deployment of low resolution mechanical/shadow masking/lithography. The low temperature of fabrication favours the use of thin silicon wafers. The configuration achieves separation of optimization requirements for efficient light absorption and carrier generation at the front and in the bulk, as well as charge carrier collection at the back.

The electrical contacts are positioned at the back surface thereby eliminating shadowing losses as these are not in the path of the incident light. Back contacts need to be optimized for maximum charge carrier collection without bothering about shading losses. A range of elements/alloys may be used to effect band-bending since both the heterojunction and surface field are at the back. All of the above features result in a very high efficiency solar cell. The open circuit voltage of the back heterojunction device is higher than that of an all-crystalline device.

Thus, in one aspect of the invention there is provided a solar cell, comprising:

a) a crystalline silicon wafer having a back surface and a front surface;

b) a silicon containing transition-passivating layer, located on said back surface, and alternating n-doped (n-a-Si:H) regions and p-doped (p-a-Si:H) regions of hydrogenated amorphous silicon located on said silicon containing transition-passivating layer to form heterojunction structures; and

c) electrical contact electrodes and current buses located on the alternating n-doped regions and p-doped regions of hydrogenated amorphous silicon for collecting electrons and holes produced in said crystalline silicon wafer upon absorption of light therein, and wherein in operation, the solar cell is oriented so that light is incident on the front surface.

The light facing side of the silicon wafer may be textured for light trapping and it may often include anti-reflection coating(s) located on the textured surface for light trapping.

Novel features of the devices produced in accordance with the present invention can be summarized as the confluence of a change from homojunction to heterojunction, front and back electrical contacts to back contacts, high temperature to low temperature processing or fabrication conditions, high resolution lithography to low resolution masking techniques, and a step favourable for the use of thin wafers.

### BRIEF DESCRIPTION OF THE DRAWINGS

The invention will now be described, by way of non-limiting examples only, reference being made to the accompanying drawings, in which:

FIG. 1 shows a cross sectional view of a configuration of a device constructed in accordance with the present invention;

FIG. 2 shows cross sectional views of two configurations (A and B) of devices; and

FIG. 3 shows a photovoltaic response measured in thin film back amorphous-crystalline heterojunction (BACH™) silicon photovoltaic devices prepared using rudimentary methods of fabrication (For structure definitions, see FIG. 2).

### DETAILED DESCRIPTION OF THE INVENTION

The present invention provides a novel low-temperature, thin film back-heterojunction, amorphous-crystalline silicon photovoltaic device. The device disclosed herein is a departure and an improvement over the existing art of back-contact photovoltaic devices as well as heterojunction photovoltaic devices. The device disclosed herein uses low temperature thin film back-heterojunctions which are prepared by low temperature deposition of undoped and doped amorphous silicon on crystalline silicon, in contrast to the high temperature diffused back junctions in existing devices.

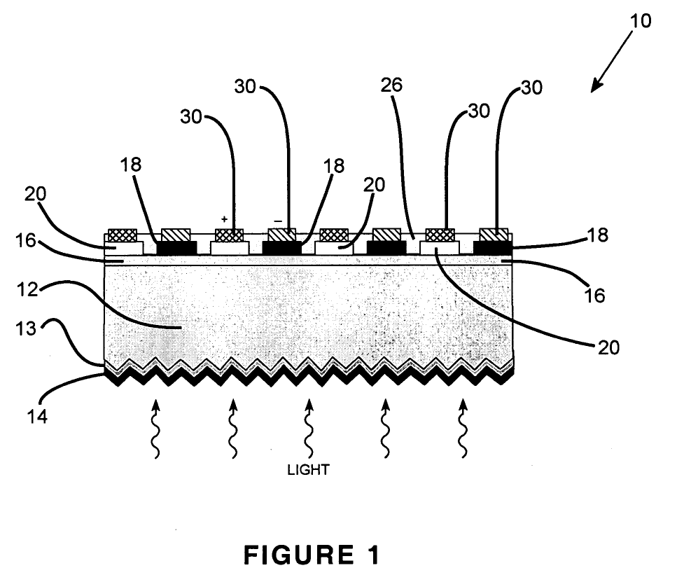

Referring first to FIG. 1, a thin film back-heterojunction, amorphous-crystalline silicon photovoltaic device shown generally at 10 includes a crystalline silicon wafer 12 which may have a thickness in a range from about 100 μm to about 300 μm.

The front surface of the crystalline silicon wafer 12, which is often textured for light trapping, usually includes a passivating layer 13 and/or an antireflection coating 14 on top of passivating layer 13. The passivating layer 13 serves to minimize surface defect density and thus reduce recombination of carriers, while the anti-reflection coating 14 serves to enhance the light trapping. Anti-reflection layer 14 and/or passivation coating 13 may include thin film layers of silicon dioxide, silicon nitride, titanium dioxide, magnesium fluoride, hydrogenated amorphous silicon, and hydrogenated amorphous carbon. Low temperature passivation can be achieved, for example, with a thin film layer of plasma enhanced chemical vapour deposition (PECVD) of hydrogenated amorphous silicon or silicon dioxide deposited on the textured surface. In addition, passivation may be achieved through a variety of thermal and/or plasma treatments, as well as using a diversity of gas compositions, as well as a range of surface treatments well known to those skilled in the art. The thin film layer on the textured surface can consist of several sub-layers/treatments.

The back surface of the crystalline silicon wafer 12 may include an intrinsic hydrogenated amorphous silicon (i-a-Si:H) transition layer 16 deposited with appropriate alternating n-doped (n-a-Si:H) regions 18 and p-doped (p-a-Si:H) regions 20 of hydrogenated amorphous silicon to create the back heterojunction structures. The total thickness of these layers 16 and 18/20 is kept as thin as practicable, typically of the order of a few angstroms to tens of nanometers.

Aluminum, silver or appropriate metal/alloy contacts 30 and current buses of optimized dimensions and composition are deposited on the doped regions on the back. A reflection layer 26 is deposited on the exposed areas of transition layer 16 and the n-and p-doped hydrogenated amorphous silicon regions 18 and 20 of the device to enable the light, which was not absorbed in the initial pass, to traverse back through the active crystalline silicon wafer 12 and thus be absorbed. The reflection layer 26 is electrically non-conducting.

Key aspects of the device include the low temperature formed heterojunction on the back surface complete with electrical contacts, while the front surface is optically transparent. The selective placement of the low temperature heterojunction on the back surface results in significant reduction of the junction area and hence leads to improved device performance. Further, the placement of the heterojunction on the back surface at low temperature is advantageous, as it permits the use of low-resolution lithography and/or shadow masking processes for producing the structures. There is no masking or shading of light on the front surface of the active crystalline silicon wafer 12, thereby permitting all light to impinge the device surface, unobstructed. The front surface is passivated with a passivating layer 13 to minimize surface defect density and thereby reducing the recombination of carriers. The front surface, being textured and having an anti-reflection coating, transmits essentially all impinging light. The anti-reflection coating 14 on the front surface of silicon wafer 12/13 is optimized only for reducing reflection losses, and is not required to be electrically conducting. Light is absorbed through the front surface of silicon wafer 12 through coatings 13 and 14 while electrical current is collected through the contacts 30 on the back surface of wafer 12. Reflection layer 26 incorporated on the back surface of silicon wafer 12 acts to back reflect the unabsorbed light and thus enhance the path length of the light, resulting in increased light absorption. Having electrical junctions and contacts on one side of the device increases the packing density of the devices and facilitates flexibility in achieving series and parallel connections.

There are several significant advantages achieved with the device disclosed herein, namely the formation of junctions on the back surface at low temperature, thereby allowing the use of low resolution lithography and/or shadow masking processes, and minimization of the heterojunction area of the device. Also, the configuration allows device fabrication through the use of thin silicon wafers. Further, the front surface of the device is free of electrodes and junctions, in contrast to the shading and light absorption by contacts in existing amorphous-crystalline silicon heterojunction devices. The delegation of electrical contacts to the back surface eliminates shading losses and permits the application of an optimal antireflection layer on the front surface, as opposed to the requirement of an antireflection layer which needs to be both optically transmissive and electrically conductive. Further, the electrical contacts and buses on the back can be optimized only for minimal series resistance, and do not require any consideration for shading since the contacts are not in the path of the incident light. Furthermore, the use of the amorphous-crystalline heterojunction (18/20-16-12) results in a higher open circuit voltage of the device when compared with an all-crystalline device.

The device may be fabricated in many ways familiar to those skilled in the art. Using a non-limiting and illustrative method, the device can be fabricated by starting with the crystalline silicon substrate, and all or essentially all device fabrication steps can be carried out by low temperature (below ˜200° C.) methods of processing. These processing steps prevent thermal damage to the thin substrates used as well as reduce the thermal budget. Device fabrication essentially involves the deposition of thin films for junction formation, contacts, back reflection, antireflection and passivation. Interfacial passivation is achieved by a variety of means which can include deposition of intrinsic or lightly doped hydrogenated amorphous silicon, PECVD or equivalently grown epitaxial silicon, and thermal and plasma treatments under various process parameters. The device fabrication is carried out with simple cost effective shadow/mechanical masking and/or low resolution photolithographic methods. For example, one simple shadow masking approach would be to use a patterned polished crystalline wafer mask on a polished back surface of the crystalline wafer 12. The front surface which has no electrodes located on it, is textured as well as covered with the aforementioned passivation layer 13 and anti-reflection coating 14. The thin n- and p-type layers (18, 20) and the electrodes 30 for carrier collection are deposited on the back. The back surface is coated with the reflection layer 26.

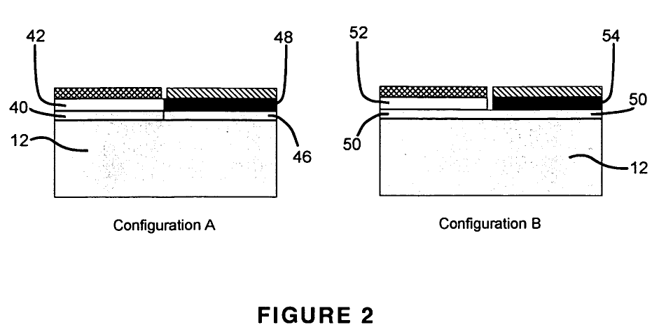

Devices made according to the present invention clearly demonstrated a photovoltaic effect in thin film back-heterojunction amorphous-crystalline silicon photovoltaic devices. The structures of two such devices are shown in FIG. 2. These structures were made using rudimentary fabrication processes, including all masking and alignment steps.

Configuration A includes a crystalline silicon wafer 12 with the back surface electrode structure produced by first masking one half of the back surface and then depositing an intrinsic hydrogenated amorphous silicon layer 40 and an n-doped hydrogenated amorphous silicon layer 42 is deposited on top of the intrinisic layer 40. The side with layers 40 and 42 located thereon is then masked and then an intrinsic hydrogenated amorphous silicon layer 46 is deposited on silicon wafer 12 and a p-doped hydrogenated amorphous silicon layer 48 on top of the intrinisic layer 46. With a mask along the centre overlapping the inner edges of layers 42 and 46, aluminum electrodes are evaporated on the n-and p-doped silicon layers.

Configuration B includes a crystalline silicon wafer 12 with the back surface electrode structure produced by first depositing an intrinsic hydrogenated amorphous silicon layer 50 on the entire back surface of silicon wafer 12. One side was then masked and an n-doped hydrogenated amorphous silicon layer 52 is deposited on top of the unmasked half of the intrinisic layer 50. The n-doped hydrogenated amorphous silicon layer 52 is then masked and a p-doped hydrogenated amorphous silicon layer 54 deposited on top of the other half of the back surface of the intrinisic layer 50. With a mask along the centre overlapping the inner edges of layers 52 and 54, aluminum electrodes are evaporated on the n-and p-doped silicon layers.

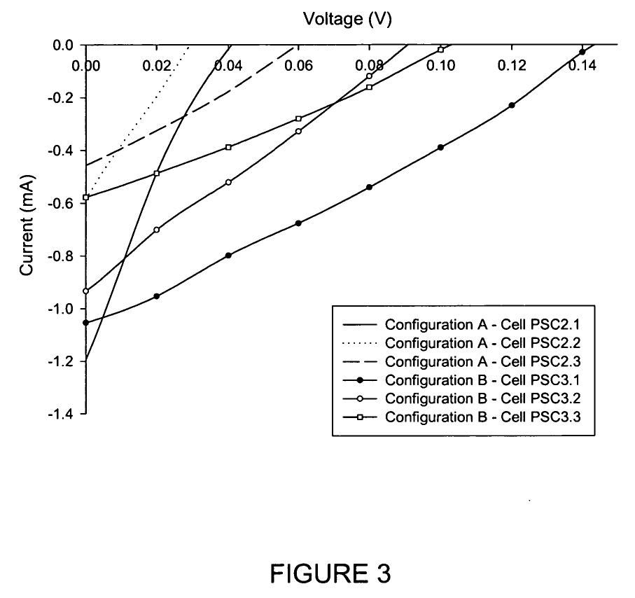

The photovoltaic response of the devices for the two configurations is shown in FIG. 3. These results show that devices produced in accordance with the present invention clearly lead to a good photovoltaic effect.

It will be understood by those skilled in the art that while the photoactive element 12 in which the carriers are photogenerated has been described with respect to silicon wafers, the photoactive element may also be a thin silicon solar cell. As a specific case, thin silicon on glass and other substrates, where the silicon is of the order of tens of microns thick and therefore not a “wafer” in the conventional case, can also be subjected to the low temperature back heterojunction configuration as disclosed herein and hence the term “wafer” is also meant to cover embodiments using these thinner films as well.

As used herein, the terms “comprises”, “comprising”, “including” and “includes” are to be construed as being inclusive and open ended, and not exclusive. Specifically, when used in this specification including claims, the terms “comprises”, “comprising”, “including” and “includes” and variations thereof mean the specified features, steps, processes or components are included. These terms are not to be interpreted to exclude the presence of other features, steps or components.

The foregoing description of the preferred embodiments of the invention has been presented to illustrate the principles of the invention and not to limit the invention to the particular embodiment illustrated. It is intended that the scope of the invention be defined by all of the embodiments encompassed within the following claims and their equivalents.

Therefore what is claimed is:

1. A solar cell, comprising:
a) a crystalline silicon wafer having a back surface and a front surface;
b) a silicon-containing transition-passivating layer, located on said back surface, and alternating n-doped (n-a-Si:H) regions and p-doped (p-a-Si:H) regions of hydrogenated amorphous silicon located on said silicon containing transition-passivating layer to form heterojunction structures; and
c) electrical contact electrodes and current buses located on the alternating n-doped (n-a-Si:H) regions and p-doped (p-a-Si:H) regions of hydrogenated amorphous silicon for collecting electrons and holes produced in said crystalline silicon wafer upon absorption of light therein, and wherein in operation the solar cell is oriented so that light is incident on said front surface.

2. The solar cell according to claim 1 including a passivating layer located on said front surface.

3. The solar cell according to claim 1 including an antireflection coating located on said front surface.

4. The solar cell according to claim 3 wherein said antireflection coating is made from a material selected from the group consisting of PECVD silicon dioxide, titanium dioxide, magnesium fluoride, hydrogenated amorphous silicon, hydrogenated amorphous carbon, titanium dioxide, silicon nitride, intrinsic hydrogenated amorphous silicon, or other appropriate alloys.

5. The solar cell according to claim 1 wherein said front surface is textured to give it a morphology which traps light reflected from said front surface.

6. The solar cell according to claim 1 including a reflective coating located on areas which include exposed areas of the intrinsic hydrogenated amorphous silicon (i-a-Si:H) transition layer located on said back surface for reflecting light which was not absorbed in its pass through a thickness of the crystalline silicon wafer, to traverse back through the crystalline silicon wafer.

7. The solar cell according to claim 1 wherein said electrical contact electrodes and current buses are made from a metal selected from the group consisting of aluminum, silver, copper and suitable appropriate metal/alloys.

8. The solar cell according to claim 1 wherein a combined thickness of said intrinsic hydrogenated amorphous silicon (i-a-Si:H) transition layer and said alternating n-doped (n-a-Si:H) regions and p-doped (p-a-Si:H) regions of hydrogenated amorphous silicon is in a range from a few angstroms to tens of nanometers.

9. The solar cell according to claim 1 wherein said silicon-containing transition-passivating layer is made from a material selected from the group consisting of intrinsic hydrogenated amorphous silicon, ion implantation of a silicon containing material, doped hydrogenated amorphous silicon, or an appropriate silicon or hydrogenated silicon alloyed amorphous, micro/nano-crystalline or epitaxial structure, or an appropriate equivalent alloy.

10. The solar cell according to claim 1 wherein said p- and n-doped layers are made from a material selected from the group consisting of intrinsic hydrogenated amorphous silicon, ion implantation of a silicon containing material, doped hydrogenated amorphous silicon, or an appropriate silicon or hydrogenated silicon alloyed amorphous, micro/nano-crystalline or epitaxial structure, or an appropriate equivalent alloy.

11. The solar cell according to claim 1 wherein said intrinsic and doped amorphous or micro/nano-crystalline layers, and or silicon containing transition-passivation layer, are formed by surface restructuring including ion implantation.

12. The solar cell according to claim 1 wherein said silicon wafer is a thin silicon layer having a thickness in a range from about 1 one to tens of microns which is formed using one of a thin film and/or epitaxial growth process.

13. The solar cell according to claim 1 wherein said silicon wafer is integrated with elements for light trapping and electrical contacts for current extraction.

14. The solar cell according to claim 1 used for radiovoltaic or electron-voltaic energy conversion devices.

15. The solar cell according to claim 2 including an antireflection coating located on said passivating layer.

16. The solar cell according to claim 9 wherein said p- and n-doped layers are made from a material selected from the group consisting of intrinsic hydrogenated amorphous silicon, ion implantation of a silicon containing material, doped hydrogenated amorphous silicon, or an appropriate silicon or hydrogenated silicon alloyed amorphous, micro/nano-crystalline or epitaxial structure, or an appropriate equivalent alloy.

17. The solar cell according to claim 1 fabricated by a method including the steps of depositing, onto said back surface of the crystalline silicon substrate, said silicon-containing transition-passivating layer on said back surface, and said alternating n-doped (n-a-Si:H) regions and p-doped (p-a-Si:H) regions of hydrogenated amorphous silicon on said silicon containing transition-passivating layer at temperatures below about 200° C.

18. The solar cell according to claim 17 wherein said passivating layer is grown on said front surface at temperatures below about 200° C., and wherein said antireflection coating is deposited onto said passivating layer at temperatures below about 200° C.

19. A solar cell, comprising:
a) a crystalline silicon wafer having a back surface and a front surface;
b) a silicon-containing transition-passivating layer, located on said back surface, said silicon-containing transition-passivating layer is made from a material selected from the group consisting of intrinsic hydrogenated amorphous silicon, ion implantation of a silicon containing material, doped hydrogenated amorphous silicon, or an appropriate silicon or hydrogenated silicon alloyed amorphous, micro/nano-crystalline or epitaxial structure, or an appropriate equivalent alloy;
c) alternating n-doped (n-a-Si:H) regions and p-doped (p-a-Si:H) regions of hydrogenated amorphous silicon located on said silicon containing transition-passivating layer to form heterojunction structures; and
d) electrical contact electrodes and current buses located on the alternating n-doped (n-a-Si:H) regions and p-doped (p-a-Si:H) regions of hydrogenated amorphous silicon for collecting electrons and holes produced in said crystalline silicon wafer upon absorption of light therein, and wherein in operation the solar cell is oriented so that light is incident on said front surface.

20. The solar cell according to claim 19 wherein said p- and n-doped layers are made from a material selected from the group consisting of intrinsic hydrogenated amorphous silicon, ion implantation of a silicon containing material, doped hydrogenated amorphous silicon, or an appropriate silicon or hydrogenated silicon alloyed amorphous, micro/nano-crystalline or epitaxial structure, or an appropriate equivalent alloy.

21. The solar cell according to claim 19 including a passivating layer located on said front surface, and an antireflection coating located on said passivating layer.
